(19) United States
(12) Patent Application Publication
(10) Pub. No.: US 2008/0011231 A1
(43) Pub. Date: Jan. 17, 2008

(54) Applicator for use in semiconductor manufacturing apparatus

(75) Inventor: Jung-Nam Kim, Hwaseong-si (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/635,746

(22) Filed: Dec. 7, 2006

(30) Foreign Application Priority Data
Jul. 12, 2006 (KR) 10-2006-0065172

(51) Int. Cl. C23C 16/00

(52) U.S. Cl. 118/723 ME; 118/723 R; 118/723 MW

(57) ABSTRACT

An applicator for use in a semiconductor manufacturing apparatus is provided, which makes it possible to reuse a relatively expensive copper pipe coil component of such an apparatus by providing a design that facilitates attachment/detachment of the copper pipe coil when replacing the quartz tube component of the applicator. The applicator of this invention includes a quartz tube having a spiral rail, an upper head portion inserted into an upper part of the quartz tube, a lower head portion inserted into a lower part of the quartz tube, and a copper pipe coil that removably mates with the spiral rail of the quartz tube through a rotation operation. In one embodiment of the apparatus, a copper pipe coil is formed as part of a structure together with an upper head portion and a lower head portion sized to mate with the respective ends of the quartz tube, then the copper pipe coil is installed and engaged with the quartz tube by a rotation along the spiral rail formed along the exterior of the quartz tube, without the use of adhesive. Consequently, the copper pipe coil does not have to be replaced when the quartz tube is etched and needs to be exchanged. Instead, only the quartz tube needs to be replaced, thereby reducing an important equipment cost.

### CROSS-REFERENCE TO RELATED PATENT APPLICATION

This application claims the benefit of Korean Patent Application No. 10-2006-0065172, filed on Jul. 12, 2006, in the Korean Intellectual Property Office, the contents of which are incorporated herein in their entirety by reference.

### TECHNICAL FIELD

The present invention relates generally to semiconductor manufacturing apparatuses, and more particularly, to an applicator for use in a semiconductor manufacturing apparatus, which is designed to facilitate reusing a copper pipe coil component by means of an attachment/detachment design for fixing the copper pipe coil in the applicator.

### BACKGROUND

In general, an auxiliary chemical reaction of plasma has been widely used in fabrication processes in the semiconductor and flat display field. As one example, a PECVD(Plasma Enhanced Chemical Vapor Deposition) can be used for manufacturing a thin film transistor and an integrated circuit for an active matrix liquid crystal display(AMLCDs). For example, a substrate can be disposed within a vacuum deposition chamber in which one pair of parallel plate electrodes are installed, according to a PECVD having a connection based on capability. A bottom electrode as one of the two electrodes, for example, which is generally called a susceptor, supports the substrate.

Another electrode, for example a top electrode, operates as a gas inflow manifold to transfer gas to a chamber, or alternatively as a shower head. During a deposition process using such an apparatus, reactive gas is supplied to the chamber through the top electrode, and high radio frequency(RF) voltage is applied between the two electrodes, thereby forming plasma in the reactive gas. Plasma provides energy and speeds up a chemical reaction.

Such a system is designed to primarily deposit material on the surface of substrate, but the material is also unavoidably deposited on other inner surfaces of chamber. Thus, after a repetitive deposition operation, a layer of material is typically piled and deposited within the chamber, and needs to be periodically removed, generally by using an in-situ dry cleaning process. Precursor gas is supplied to the chamber by an in-situ technology. Then glow discharge plasma is applied partially to the precursor gas within the chamber, thus generating reactive species. The reactive species are selected to react with the deposited material, thereby cleaning the surface of the chamber and forming volatile compounds that can then be eliminated as a gas exhaust.

However, this in-situ cleaning technology has some shortcomings. First, it is generally inefficient to use plasma within a chamber in order to generate reactive species. Such an operation typically needs to use a relatively high power in order to attain an acceptable cleaning rate. But, when such a high power level is used, a hardware within the chamber may be damaged shortening its useful life. It may be prohibitively expensive to replace such damaged hardware, thereby increasing the manufacturing cost per substrate through use of a deposition system. In a fiercely competitive field such as in semiconductor manufacturing, in which substrate cost represents a very important proportion of the costs, it may be undesirable or impractical to accommodate the increased work expenses due to a periodic replacement of parts damaged in the cleaning process.

Still another problem in the in-situ reaction chamber dry cleaning process is that the high power needed to get an acceptable cleaning rate may cause a generation of residuals or byproducts that may damage exposed parts and/or may not be easily eliminated in any way other than to have the chamber interior surface be wiped clean physically. For example, in an Si₃N₄ deposition system using NF₃ for the cleaning, compounds having the general chemical formula NₓH_{y}F_{z} may be generated. Such an ammonium-type compound may be deposited within a vacuum pump, which may adversely affect the reliability of the pump, which is used to form and maintain a vacuum environment for preparing the substrate.

Deposition chamber or process kit parts, for example, heater, shower head, clamp ring, etc., are typically manufactured of ceramic or aluminum, and these parts/components are often cleaned by using NF₃ plasma containing excited F*(gas) species. During such a cleaning process, some amount of AlₓF_{y} may be formed on an exposed surface of the chamber and process kit parts. The amount of the AlₓF_{y} material formed substantially increases according to the level of ion bombardment based on a high plasma energy level. Thus, a considerable amount of AlₓF_{y} may be formed within the system. Unfortunately this material cannot be etched and removed by any well-known chemical process. Instead, in such cases, the reaction needs to be stopped and the chamber opened so as to physically wipe out the interior surface of the chamber and remove the deposited material.

U.S. Pat. No. 4,988,644, which is incorporated herein by reference, discloses a remote plasma generator having a cooling jacket. But, the cooling jacket of this patent is limited to a gas input tube of a resonant cavity and a gas tube provided on a quartz outflow tube. A gas passage extending through the resonant cavity and the resonant cavity itself are not cooled by the cooling jacket, thus the temperature of the quartz tube within the resonant cavity is not still controlled with this system.

U.S. Pat. No. 5,262,610, which is incorporated herein by reference, discloses another type of remote plasma generator wherein the generator includes a cooling water jacket for coupling a VHF(Very High Frequency) applicator to a matching device, and a double-wall quartz inflow tube. But, the cooling jacket of this patent does not extend to the neighborhood of the gas tube disposed within the VHF applicator. Thus, in this design, the highest temperature region of the gas tube, which is a region having the highest possibility for a generation of a crack and/or for particle deposition, extends to an VHF applicator that is never cooled.

These and other limitations and disadvantages of prior art systems are overcome in whole or at least in part by the semiconductor plasma generator/applicator apparatus of this invention.

### SUMMARY OF THE INVENTION

An exemplary embodiment of the present invention provides a plasma applicator for use in a semiconductor manufacturing apparatus, which is capable of reducing expenses by reusing a copper pipe coil of high cost when a quartz tube of the applicator has become etched and so needs to be replaced.

According to some embodiments of the invention, an applicator for use in a semiconductor manufacturing apparatus includes a quartz tube having a spiral rail, an upper head portion inserted into an upper part of the quartz tube, a lower head portion inserted into a lower part of the quartz tube, and a copper pipe coil that is inserted and fixed along the spiral rail of the quartz tube through a rotation operation.

The upper head portion and the lower head portion may have a spiral rail formed in the respective interior parts thereof.

The upper head portion and the lower head portion may be desirably formed in a body together with the copper pipe coil.

The copper pipe coil may, when in use, cool the quartz tube by means of cooling water flowing through the interior thereof.

### BRIEF DESCRIPTION OF THE DRAWINGS

The present invention will become more fully understood from the detailed description provided herein below and the accompanying drawings which are provided by way of illustration only, and thus should not be regarded as limiting of the present invention, and wherein:

FIG. 1 schematically illustrates the general structure of a plasma deposition apparatus including a plasma applicator;

FIG. 2 schematically illustrates a conventional type of plasma applicator for use with a plasma deposition apparatus as shown in FIG. 1;

FIG. 3A schematically illustrates a perspective view of a copper pipe coil in association with a quartz plasma tube of a conventional type of plasma applicator as shown in FIG. 2;

FIG. 3B schematically illustrates in a vertical cross-sectional view how the copper pipe coil of FIG. 3A is installed relative to the quartz plasma tube in a conventional configuration;

FIG. 4 schematically illustrates in detail a structure of an applicator according to certain embodiments of this invention;

FIG. 5A is a schematic perspective view illustrating an installation of a copper pipe coil in association with the quartz tube of FIG. 4;

FIG. 5B is a schematic vertical sectional view illustrating an installation of a copper pipe coil in association with the quartz tube of FIG. 4;

FIG. 5C is a schematic perspective view illustrating the quartz tube and the copper pipe coil shown in FIG. 4 in a separated state; and

FIG. 6 is a schematic vertical side view of the quartz tube shown in FIG. 4.

### DETAILED DESCRIPTION OF THE INVENTION

Plasma applicators for semiconductor fabrication may be generally divided into a wave guide type and a cavity type. The cavity type applicators may be subdivided into a resonant type and a non-resonant type. The wave guide type applicators may be subdivided into cylindrical and rectangular types etc. according to cross-sectional shape, and also may be divided into TEmn types and TMmn types etc., according to an electromagnetic field distribution mode of the wave guide interior. In this description, m and n are used to indicate a natural number, including 0, in which, according to a frequency or wavelength of electromagnetic wave and a sectional size of the wave guide, a lowest frequency mode existing within the wave guide may be a basic mode, the cylindrical wave guide being for TE11 and the rectangular wave guide being for TE10. The resonant cavity type applicators may be again divided into TEmnp and TMnmp types etc., according to an electromagnetic field distribution type within the cavity. In particular, what may be called a multi-mode cavity applicator is one for which plural modes can simultaneously exist within the cavity.

The VHF applicator generates plasma from a high frequency power and then generates process gas, in which UHF (UltraHigh Frequency: as a decimeter wave or very high frequency) of about 300˜3000 MHz, which is generally higher than ultrashort wave, can be used.

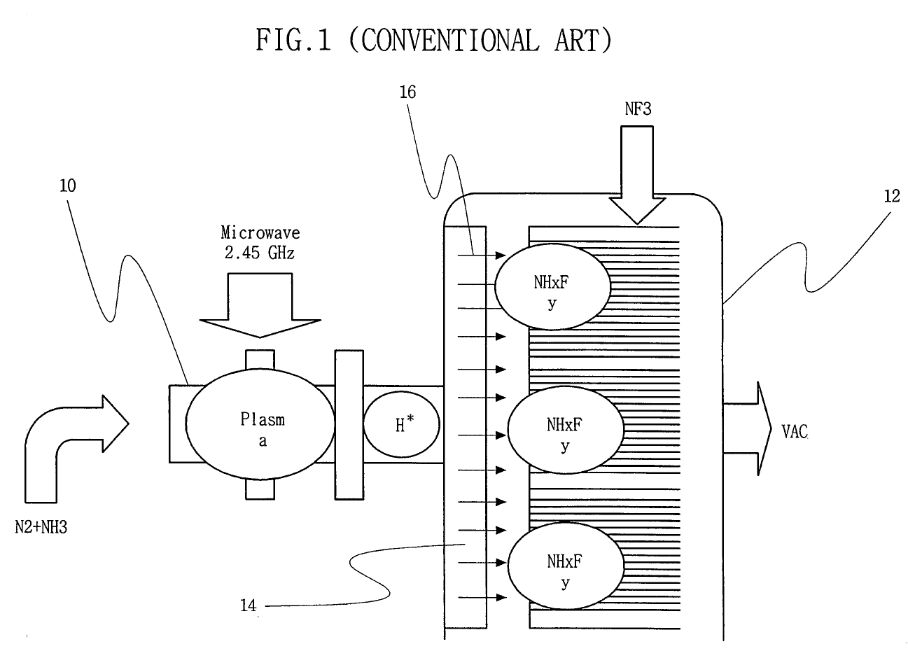

FIGS. 1, 2, 3A and 3B herein illustrate conventional quartz tube/copper coil configurations for such an apparatus. By briefly reviewing such conventional configurations, the advantages and novel features of this invention will be better understood.

FIG. 1 illustrates a conventional structure of a general deposition/etching apparatus.

The etching apparatus of FIG. 1 includes a conventional applicator 10 for generating plasma necessary for microwave energy to detach unnecessary electromagnetic particles of NH₃ and N₂ gas, and a process chamber 12 for performing a deposition process by using plasma generated from the applicator 10.

In one side inner wall of the process chamber 12, a slit 14 is formed to evenly supply plasma gas generated from the applicator 10 to a lower part from an upper part of the chamber. Further, plural slots in which wafers are accumulated are also formed within the process chamber 12, as is known in this art.

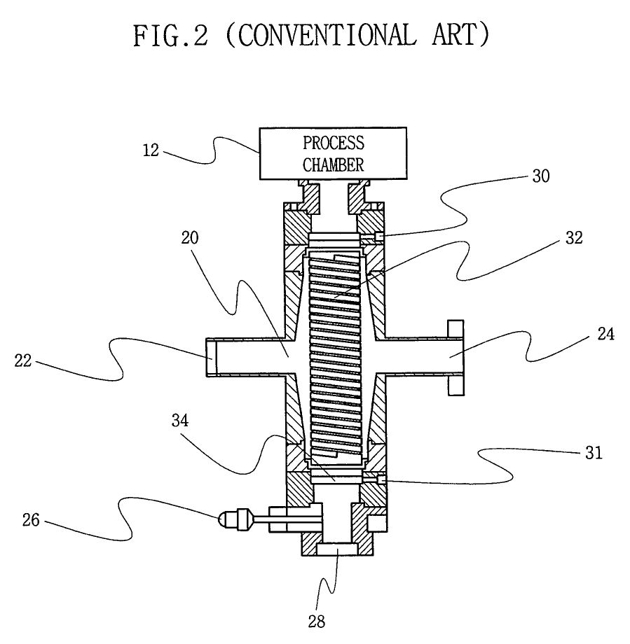

FIG. 2 illustrates in greater detail a structure of the applicator 10 as shown in FIG. 1.

In the structure of the applicator 10, a chamber 20 has an internal space that is formed in a wave guide shape, and a reflector 22 is provided at a first end of the chamber 20 to reflect short microwaves that do not themselves form plasma so as to form additional plasma. Further, a microwave input terminal 24 is installed at a second, opposite end of the reflector 22, to induce microwaves. A gas supply line 26 is adapted to another side of the chamber 20 to supply NH₃ and N₂ gases. A UV(Ultraviolet) lamp 28 applies UV light to gases supplied by the gas supply line 26, thereby providing the gases in a free electron state. A cooling water supply line 30 supplies cooling water. A copper pipe coil 32 is connected to the cooling water supply line 30 to carry the cooling water so as to remove heat generated in forming plasma. A cooling water discharge line 31 discharges cooling water passed through the copper pipe coil 32. A quartz tube 34 is installed so as to extend between the UV lamp 28 and the process chamber 12, and such tube is typically permanently affixed to the copper pipe coil 32, such as with adhesive.

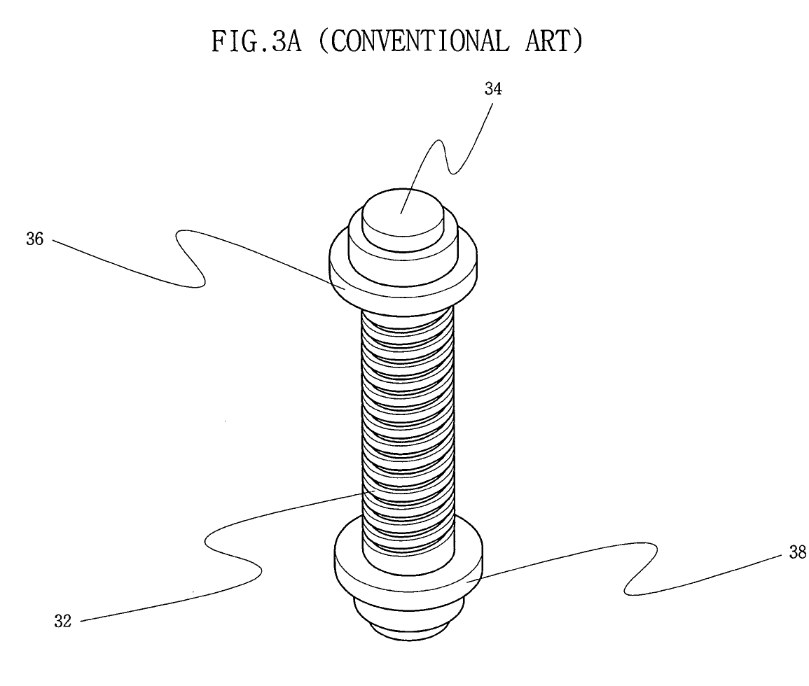

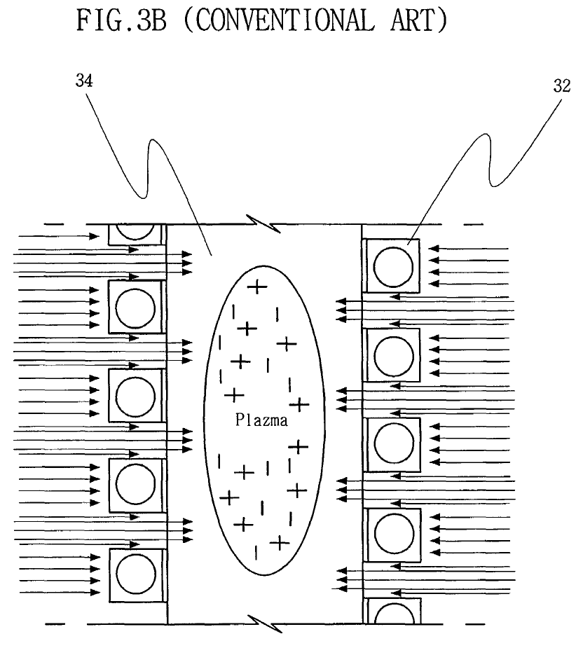

FIG. 3A is a perspective view illustrating an installation of the copper pipe coil 32 relative to the quartz tube 34 of FIG. 2, and FIG. 3B is a vertical sectional view further illustrating an installation of copper pipe coil 32 relative to the quartz tube 34 shown in FIG. 2.

With reference to FIGS. 3A and 3B, there are a quartz tube 34, an upper head 36 portion inserted into the quartz tube 34, a lower head portion 38 inserted into the quartz tube 34, and a copper pipe coil 32 inserted and fixed to the quartz tube 34.

The copper pipe coil 32 is inserted into the quartz tube 34 and then is typically fixed thereto with the use of an adhesive.

Describing the conventional apparatus in more detail by reference to FIGS. 1, 2, 3A and 3B, there is a slot within the process chamber 12 in which a plurality of wafers can be adapted. A slit 14 formed in one side wall of the process chamber 12 allows plasma gas to be supplied to the plurality of wafers through plural holes 16 formed in the slit 14. High frequency power (2.45 GHz) generated from a high frequency power generator(not shown) is applied through the microwave input terminal 24 (FIG. 2), and N₂ and NH₃ gases are supplied through gas supply line 26. When both the high frequency power and N₂ and NH₃ gases are simultaneously supplied, plasma is generated to detach unnecessary electromagnetic particles of N₂ and NH₃ gases within the chamber 20. At the same time, reflector 22 reflects short microwave radiation that cannot form plasma to the quartz tube 34 and so forms additional plasma. The UV lamp 28 applies UV light to gas supplied by the gas supply line 26, thereby providing the gas in a free electron state. The copper pipe coil 32 is formed of a copper pipe of a coil type through which cooling water supplied from the cooling water supply line 30 may circulate. Heat generated when the cooling water circulates and plasma is formed is removed by the cooling water passing through the copper pipe coil 32 thereby preventing the quartz tube 34 from being broken by excessive heat buildup. The cooling water circulating through the copper pipe coil 32 is discharged through the cooling water discharge line 31. Plasma gas formed in the chamber 20 is evenly supplied to plural wafers laminated in the slots of the process chamber 12 through plural holes 16 of the slit 14. Through these operations, the applicator 10 generates plasma for negative and/or positive ions as necessary when microwave energy at high frequency power detaches unnecessary electromagnetic particles of NH₃ and N₂ gases. The generated plasma gas is supplied to the process chamber 12. In the process chamber 12, SiO₂ on the surface of a semiconductor wafer is removed by a chemical reaction with NF₃ gas inflowing through the gas line as shown in FIG. 1, thus preventing a negative oxidation from growing on the surface of wafer for a long time. The chemical reaction that occurs in process chamber 12 can be represented by the following chemical expression 1.

H*+NF₃→NHₓF_{y}(e.g., NH₄F, NH₄HF, etc.) [Chemical Expression 1]

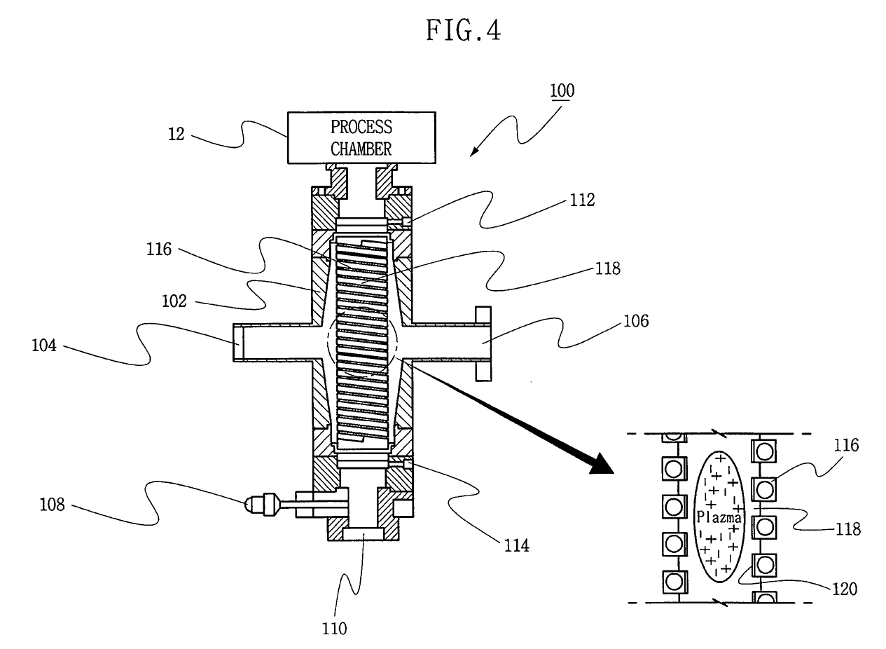

The applicator 10 in a conventional semiconductor manufacturing apparatus should ordinarily be replaced after every PM (Process Management) period when quartz tube 34 is etched by plasma. With the conventional plasma applicator technology as described above, the copper pipe coil 32, which is a relatively expensive apparatus component, cannot be reused because the copper pipe coil 32 is adhered to the quartz tube 34 through the use of adhesive. That is, when the quartz tube 34 is etched by plasma and so should be replaced, the quartz tube 34 and the copper pipe coil 32 both need to be replaced together producing unnecessary expenses. The applicator design of the present invention, however, as illustrated in FIGS. 4, 5A, 5B, 5C and 6, overcomes this drawback and disadvantage.

Hereinafter, exemplary embodiments of the present invention will be described in detail with reference to FIGS. 4 to 6. It will be understood by those skilled in the art that the present invention can be embodied in numerous different ways and illustrated by different drawings and accordingly is not limited to the following described embodiments. The following various embodiments are intended to be merely exemplary in nature.

FIG. 4 is a schematic cross-section of an applicator structure 100 according to some embodiments of this invention. The structure of applicator 100 will be described below.

A chamber 102 has an internal space that is formed in a wave guide type, and a reflector 104 is provided at a first end of the chamber 102 to reflect short microwave radiation that cannot form plasma to quartz tube 118 and so to form plasma. A microwave input terminal 106 is installed at a second end opposite the reflector 104, to induce microwave radiation. A gas supply line 108 is adapted to another side of the chamber 102 to supply NH₃ and N₂ gases. A UV lamp 110 applies UV light to the gases supplied by the gas supply line 108, thereby providing the gases in a free electron state. A cooling water supply line 112 supplies cooling water. One end of a copper pipe coil 116 is connected to the cooling water supply line 112 to remove at least a substantial portion of the heat generated in forming plasma. A cooling water discharge line 114 is coupled to the other end of copper pipe coil 116 to provide a discharge of the cooling water passed through the copper pipe coil 1 16. A quartz tube 118 is installed so as to extend between the UV lamp 110 at one end of the applicator 100 and the process chamber 12 at the opposite end so as to fix the copper pipe coil 116 in place. In accordance with this invention, a spiral rail 120 into which the copper pipe coil 116 can be inserted through a rotation is formed along the outer surface of the quartz tube 118.

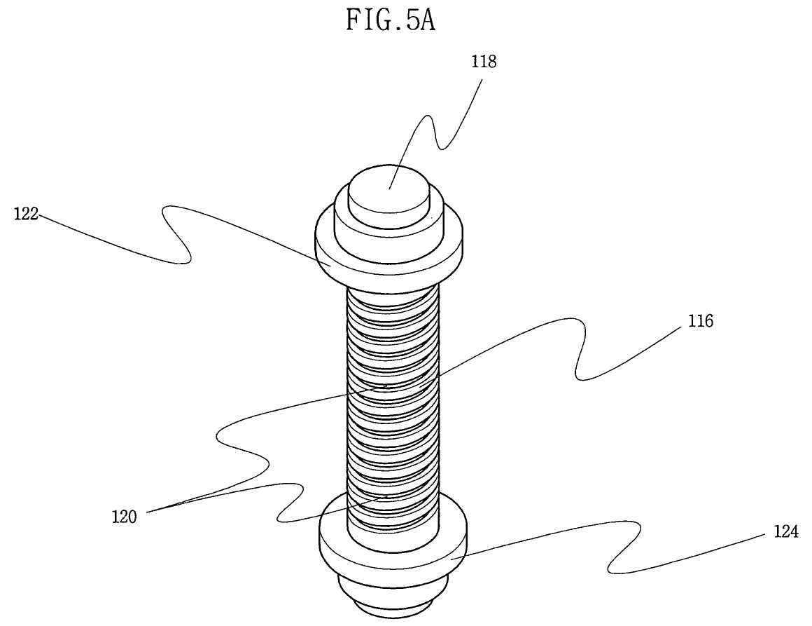

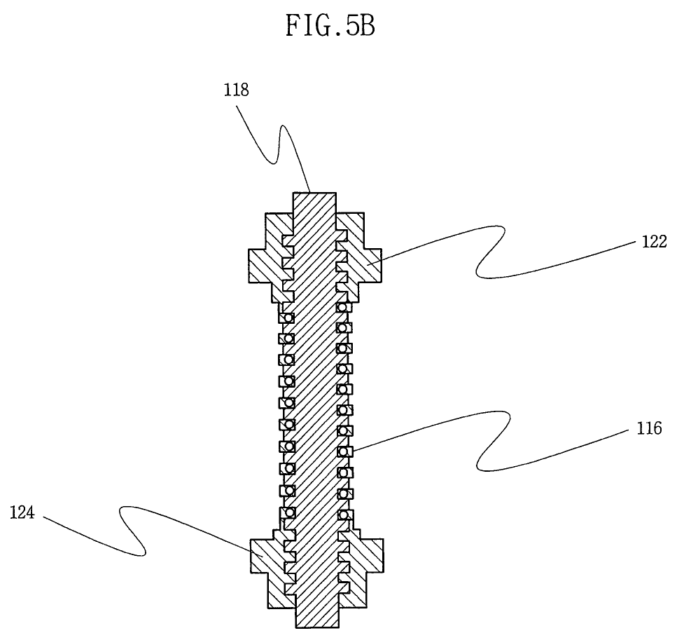

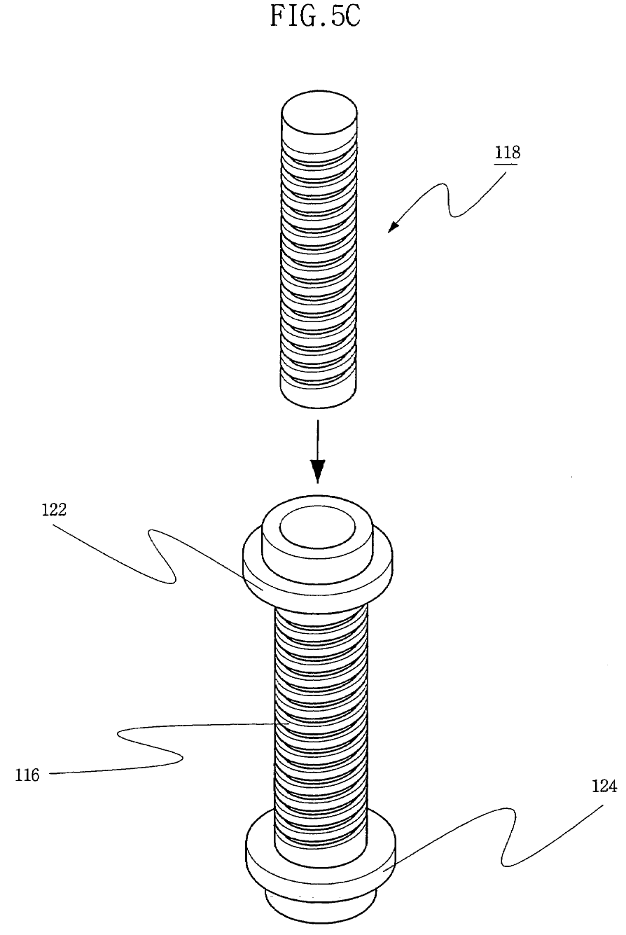

FIG. 5A is a perspective view illustrating how the copper pipe coil 116 mates with the exterior of the quartz tube 118 as shown in FIG. 4. FIG. 5B is a vertical sectional view of the assembled structure shown in FIG. 5A illustrating how the spiral-shaped copper pipe coil 116 engages with a matching spiral pattern along the outer surface of the quartz tube 118. FIG. 5C is a perspective view illustrating the quartz tube 118 and the structure that includes copper pipe coil 116 as shown in FIG. 5A before these two components are mated to one another.

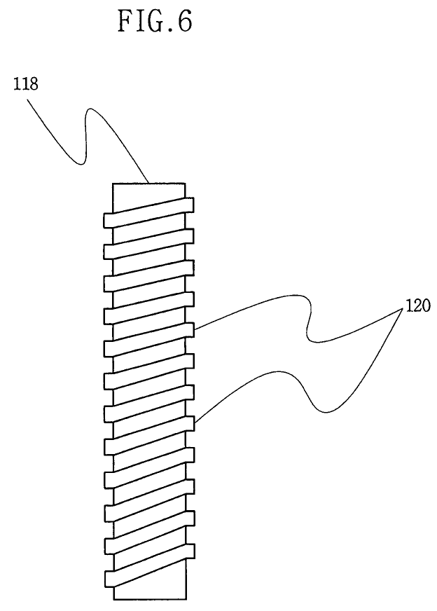

FIG. 6 is a vertical side view of the quartz tube 118 showing the spiral pattern along the exterior surface of the tube designed to mate with the spiral shape of copper pipe coil 116.

Referring to these several drawings, a quartz tube 118 has a spiral rail 120 along its exterior surface. An upper head portion 122 is inserted into an upper part of the quartz tube 118. A lower head portion 124 is inserted into a lower part of the quartz tube 118. A copper pipe coil 116 is inserted and fixed along the exterior of quartz tube 118 through a rotation operation along the spiral rail 120 of the quartz tube 118, in an operation somewhat comparable to screwing an internally-threaded cap onto the externally-threaded mouth of a bottle.

With further reference to FIGS. 4 to 5A and 5C, a slot (not shown in these drawings) is installed within process chamber 12, adapted to hold a plurality of semiconductor wafers, A slit (not shown in these drawings) is formed in one side wall of the process chamber, and plasma gas from applicator 100 is supplied to the plurality of wafers within the chamber through plural holes formed in the slit. High frequency power (2.45 GHz) generated from a high frequency power generator(not shown) is applied through a microwave input terminal 106, and N₂ and NH₃ gases are supplied through a gas supply line 108. When the high frequency power and N₂ and NH₃ gases are being supplied to applicator 100, plasma is generated to detach unnecessary electromagnetic particles of N₂ and NH₃ gases within the chamber 102.

At the same time, a reflector 104 reflects short microwave radiation that cannot form plasma to the quartz tube 118, and thereby forms additional plasma. A UV lamp 110 applies UV light to the gases supplied by the gas supply line 108 thereby providing the gases in a free electron state. The copper pipe coil 116 is formed of a copper pipe of a coil type so that cooling water introduced through the is cooling water supply line 112 may circulate. Heat generated when the plasma is formed is removed by the cooling water passing through the copper pipe coil 116 thereby preventing the quartz tube 118 from overheating and being broken. The cooling water circulating through the copper pipe coil 116 is discharged through the cooling water discharge line 114. Plasma gas formed in the chamber 102 is evenly supplied to the plurality of semiconductor wafers laminated in the slot of the process chamber 12 through plural holes of the slit. Through these operations, the applicator 100 generates plasma for negative and positive ions as necessary and microwave energy as high frequency power detaches unnecessary electromagnetic particles of NH₃ and N₂ gases. The generated plasma gas is applied to the process chamber 12. In the process chamber 12, SiO₂ on the surface of the semiconductor wafers is removed by a chemical reaction with NF₃ gas inflowing through a gas line (as shown in FIG. 1 in connection with a conventional apparatus), thus preventing a negative oxidation from growing on the surface of the wafers for a long time. In the interior of the upper head portion 122 and the lower head portion 124 of the applicator 100 (as seen in FIGS. 5A, 5B and 5C), a spiral rail (or threaded section) is formed designed to mate with the portions of the spiral rail 120 at the top and bottom respectively of quartz tube 118. When the quartz tube 118 is etched and thereby damaged by a generation of plasma and therefore needs to be replaced, the upper head portion 122 and the lower head portion 124 are rotated (for example, in a left direction) to separate the copper pipe coil 116 from the quartz tube 118. After replacing the damaged/used quartz tube 118 with a new quartz tube 118, the lower head portion 124 is inserted in the spiral rail 120 formed in the quartz tube 118 (as shown in FIG. 5B and FIG. 6), and then is rotated in an opposite direction (for example, in a right direction). Thus, the copper pipe coil 116, included as part of a structure together with the upper head portion 122 and the lower head portion 124, can be reused and installed and fixed to the new quartz tube 118.

In the conventional art in this field, copper pipe coil 32 (see FIGS. 3A and 3B) is formed in a body together with upper head portion 36 and lower head portion 38 and is then adhered to quartz tube 34 using adhesive. In this case, when the quartz tube 34 is etched and damaged by plasma generation and should be replaced, it is difficult or impossible to exchange only the quartz tube 34, and so the entire assembly including copper pipe coil 32 formed in a structure with the upper head portion 36 and the lower head portion 38 would be exchanged in its entirety. However, according to embodiments of this invention, the copper pipe coil 116 formed in a structure with the upper head portion 122 and the lower head portion 124 can relatively easily be separated from the quartz tube 118. Thus, the copper pipe coil 116 can be reused when the quartz tube 118 becomes etched and needs to be replaced by exchanging only the quartz tube 118. Accordingly, a significant equipment cost savings can be realized.

As described above, according to embodiments of this invention, in a plasma applicator for use in a semiconductor manufacturing apparatus, a copper pipe coil formed as part of a structure with an upper head portion and a lower head portion can be mated with a quartz tube, whereby the copper pipe coil can be removably installed and mated with the quartz tube by a rotation along a spiral rail formed along the exterior of the quartz tube, without using adhesive. Consequently, the copper pipe coil does not have to be replaced when the quartz tube becomes etched and needs to be exchanged, but instead only the quartz tube can be replaced, thereby reducing an equipment cost.

While the present invention has been particularly shown and described with reference to exemplary embodiments thereof, it will be understood by those skilled in the art that various changes in form and details may be made therein without departing from the spirit and scope of the present invention as defined by the appended claims. Accordingly, these and other changes and modifications are considered to be within the true spirit and scope of the invention as defined by the appended claims.

It will also be apparent to those skilled in the art that modifications and variations can be made in the present invention without deviating from the spirit or scope of the invention. Thus, it is intended that the present invention cover any such modifications and variations of this invention within the full scope of the appended claims and their equivalents. Accordingly, these and other changes and modifications are considered to be within the true spirit and scope of the invention as defined by the appended claims.

What is claimed is:

1. A plasma applicator for use in a semiconductor manufacturing apparatus, the apparatus comprising:
a quartz tube having a spiral rail along its exterior surface;
an upper head portion that mates with an upper part of the quartz tube;
a lower head portion that mates with a lower part of the quartz tube; and
a pipe coil sized and shaped to removably mate with the spiral rail of the quartz tube through a rotation operation.

2. The applicator of claim 1, wherein the upper head portion and the lower head portion each have an interior surface with a spiral rail portion sized and shaped to engage the spiral rail portions at the respective ends of the quartz tube.

3. The applicator of claim 1, wherein the upper head portion and the lower head portion are formed as parts of a structure together with the pipe coil.

4. The applicator of claim 1, said applicator further comprising a fluid inlet connection at a first end of the pipe coil and a fluid outlet connection at a second end of the pipe coil whereby a cooling fluid can be flowed through the pipe coil to cool the quartz tube.

5. The applicator of claim 4 further comprising said cooling fluid wherein said cooling fluid is water.

6. The applicator of claim 1 wherein said pipe coil is made of copper.

7. The applicator of claim 1, said applicator further comprising a chamber defining an internal space to contain the quartz tube, a reflector element to reflect microwave radiation, a microwave input terminal, a gas supply line, a UV lamp, and a plasma connection port for coupling the internal space of the chamber to a process chamber.

8. Apparatus for fabricating semiconductor wafers, said apparatus comprising a process chamber for exposing a plurality of semiconductor wafers to a plasma treatment, said process chamber being coupled to a plasma applicator comprising:
a quartz tube having a spiral rail along its exterior surface;
an upper head portion that mates with an upper part of the quartz tube;
a lower head portion that mates with a lower part of the quartz tube; and
a pipe coil sized and shaped to removably mate with the spiral rail of the quartz tube through a rotation operation.

9. An apparatus according to claim 8, wherein the upper head portion and the lower head portion each have an interior surface with a spiral rail portion sized and shaped to engage the spiral rail portions at the respective ends of the quartz tube.

10. An apparatus according to claim 8, wherein the upper head portion and the lower head portion are formed as parts of a structure together with the pipe coil.

11. An apparatus according to claim 8, said applicator further comprising a fluid inlet connection at a first end of the pipe coil and a fluid outlet connection at a second end of the pipe coil whereby a cooling fluid can be flowed through the pipe coil to cool the quartz tube.

12. An apparatus according to claim 11, wherein said cooling fluid wherein said cooling fluid is water.

13. An apparatus according to claim 8, wherein said pipe coil is made of copper.

14. An apparatus according to claim 8, wherein said applicator further comprises a chamber defining an internal space to contain the quartz tube, a reflector element to reflect microwave radiation, a microwave input terminal, a gas supply line, a UV lamp, and a plasma connection port for coupling the internal space of the chamber to said process chamber.

15. A method for removably engaging a spiral cooling pipe coil with the exterior of a quartz tube used for generating plasma as part of a plasma applicator, said method comprising the steps of: providing a spiral rail along the outer surface of said quartz tube, said spiral rail being sized and shaped to mate with the spiral cooling pipe coil; and, engaging the cooling pipe coil to the quartz tube by a rotation operation in a first direction.

16. The method of claim 15 further comprising the step of flowing a cooling fluid into and out of the cooling pipe coil while the coil is in engagement with the quartz tube.

17. The method of claim 16 further comprising the step of generating plasma in the plasma applicator while cooling fluid is flowed through the cooling pipe coil

18. The method of claim 15 further comprising the step of disengaging the cooling pipe coil from the quartz tube by a rotation operation in a direction opposite to said first direction.
